(19) United States
(12) Patent Application Publication
(10) Pub. No.: US 2026/0173322 A1
(43) Pub. Date: Jun. 18, 2026

(54) COOLING BOX, ELECTRICAL CONNECTION MODULE AND CHARGING DEVICE

(71) Applicants: Tyco Electronics (Suzhou) Ltd., Suzhou City (CN); Tyco Electronics (Shanghai) Co., Ltd., Shanghai (CN); Tyco Electronics Technology (SIP) Co., Ltd., Suzhou (CN)

(72) Inventors: Houtie (Jack) Liu, Suzhou (CN); Fangyue (Jason) Zhu, Shanghai (CN); Jinshun (Jet) Wang, Suzhou (CN); Super Wu, Suzhou (CN)

(73) Assignees: Tyco Electronics (Suzhou) Ltd., Suzhou City (CN); Tyco Electronics (Shanghai) Co., Ltd., Shanghai (CN); Tyco Electronics Technology (SIP) Co., Ltd., Suzhou (CN)

(21) Appl. No.: 19/420,897

(22) Filed: Dec. 16, 2025

(30) Foreign Application Priority Data
Dec. 16, 2024 (CN) 202423100587.1

(51) Int. Cl. H05K 7/20; H01R 4/02; H01R 13/00; H01R 13/502

(52) U.S. Cl. CPC H05K 7/2039; H01R 4/029; H01R 13/005; H01R 13/502; H05K 7/20254; H05K 7/20272

(57) ABSTRACT

A cooling box includes a box body with a bottom opening, a bottom cover installed on the bottom opening of the box body, a plurality of pipe joints integrally formed with the box body and communicated with an interior of the box body to allow a cooling liquid to flow into or out of the box body through the pipe joints, and a heat-conductive electric insulation layer wrapped around an outside of the box body. An exterior of the bottom cover is wrapped by the heat-conductive electric insulation layer or by a heat-conductive electric insulation cap that is fitted onto a lower part of the box body. The cooling box thermally contacts a charging terminal to transfer heat of the charging terminal to the cooling liquid inside the box body through the heat-conductive electric insulation layer and the bottom cover to cool the charging terminal.

### CROSS-REFERENCE TO RELATED APPLICATION

This application claims the benefit of the filing date under 35 U.S.C. § 119(a)-(d) of Chinese Patent Application No. 202423100587.1, filed on Dec. 16, 2024.

### FIELD OF THE INVENTION

The present invention relates to a cooling box, an electrical connection module comprising the cooling box, and a charging device comprising the electrical connection module.

### BACKGROUND OF THE INVENTION

A charging dock commonly includes a charging dock housing, a charging terminal set in the charging dock housing, and a charging cable electrically connected to the charging terminal. In order to improve charging speed, it is necessary to increase the charging current. Currently, the charging current requirement is as high as 600 A, and it may increase to 1000 A in the future. When this high current flows through the charging cable and charging terminal, it will cause a sharp rise in the temperature inside the charging dock housing and the charging cable. In order to prevent excessive temperature rise, the diameter of the charging cable and the size of the charging terminal are increased, but this will increase the volume and weight of the charging dock product and lead to higher costs.

In order to prevent the temperature of the charging cable and terminal from rising sharply, a liquid cooling scheme has recently been proposed, which includes a cooling box. However, existing cooling boxes require welding of pipe joints and pasting of heat-conductive electric insulation films, making the manufacturing process complex and costly. In addition, the interior of the existing cooling box is a rectangular cavity, and the flow of cooling liquid at its corners is not smooth, which will affect the normal flow of cooling liquid and seriously affect the cooling capabilities.

### SUMMARY OF THE INVENTION

A cooling box includes a box body with a bottom opening, a bottom cover installed on the bottom opening of the box body, a plurality of pipe joints integrally formed with the box body and communicated with an interior of the box body to allow a cooling liquid to flow into or out of the box body through the pipe joints, and a heat-conductive electric insulation layer wrapped around an outside of the box body. An exterior of the bottom cover is wrapped by the heat-conductive electric insulation layer or by a heat-conductive electric insulation cap that is fitted onto a lower part of the box body. The cooling box thermally contacts a charging terminal to transfer heat of the charging terminal to the cooling liquid inside the box body through the heat-conductive electric insulation layer and the bottom cover to cool the charging terminal.

### BRIEF DESCRIPTION OF THE DRAWINGS

Features of the present invention will become more apparent by describing in detail exemplary embodiments thereof with reference to the accompanying drawings, in which:

FIG. 1 shows an illustrative perspective view of an electrical connection module according to an exemplary first embodiment of the present invention;

FIG. 2 shows an illustrative exploded view of an electrical connection module according to an exemplary first embodiment of the present invention;

FIG. 3 shows an illustrative exploded view of the charging cable and charging terminal of the electrical connection module according to an exemplary first embodiment of the present invention;

FIG. 3A shows a cross-sectional view of a charging cable according to an exemplary first embodiment of the present invention;

FIG. 4 shows a transverse sectional view of the cooling box of the electrical connection module according to an exemplary first embodiment of the present invention;

FIG. 5 shows an illustrative perspective view of a cooling box according to an exemplary first embodiment of the present invention when viewed from the top, where the heat-conductive electric insulation layer is not shown;

FIG. 6 shows an illustrative perspective view of a cooling box according to an exemplary first embodiment of the present invention when viewed from the bottom, where the heat-conductive electric insulation layer is not shown;

FIG. 7 shows an illustrative exploded view of a cooling box according to an exemplary first embodiment of the present invention when viewed from the bottom, where the heat-conductive electric insulation layer is not shown;

FIG. 8 shows an illustrative perspective view of an electrical connection module according to an exemplary second embodiment of the present invention;

FIG. 9 shows an illustrative exploded view of an electrical connection module according to an exemplary second embodiment of the present invention;

FIG. 10 shows an illustrative exploded view of the charging cable and charging terminal of the electrical connection module according to an exemplary second embodiment of the present invention;

FIG. 10A shows a cross-sectional view of a charging cable according to an exemplary second embodiment of the present invention;

FIG. 11 shows a transverse sectional view of the cooling box of an electrical connection module according to an exemplary second embodiment of the present invention;

FIG. 12 shows an illustrative perspective view of a cooling box according to an exemplary second embodiment of the present invention when viewed from the top, where the heat-conductive electric insulation layer is not shown;

FIG. 13 shows an illustrative perspective view of a cooling box according to an exemplary second embodiment of the present invention when viewed from the bottom, where the heat-conductive electric insulation layer is not shown;

FIG. 14 shows an illustrative exploded view of a cooling box according to an exemplary second embodiment of the present invention when viewed from the bottom, where the heat-conductive electric insulation layer is not shown; and

FIG. 15 shows an illustrative exploded view of a cooling box according to an exemplary second embodiment of the present invention, in which the heat-conductive electric insulation cap has not yet been fitted onto the body of the cooling box.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

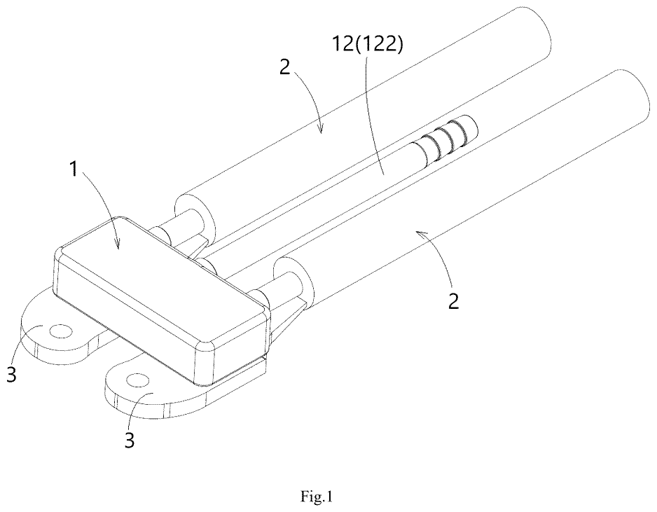

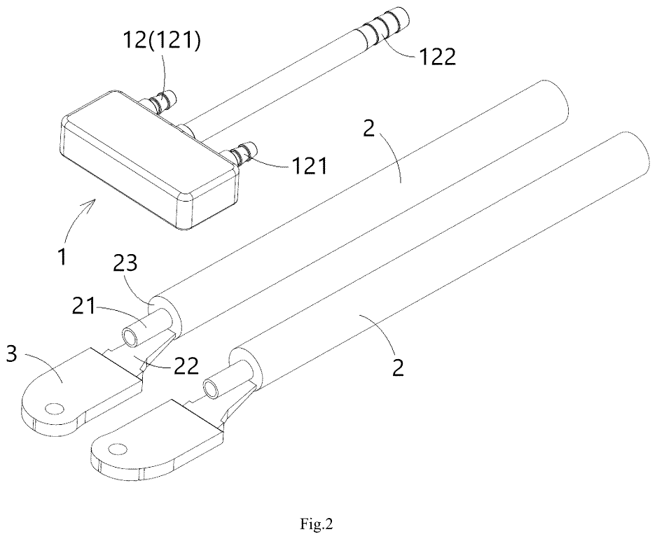

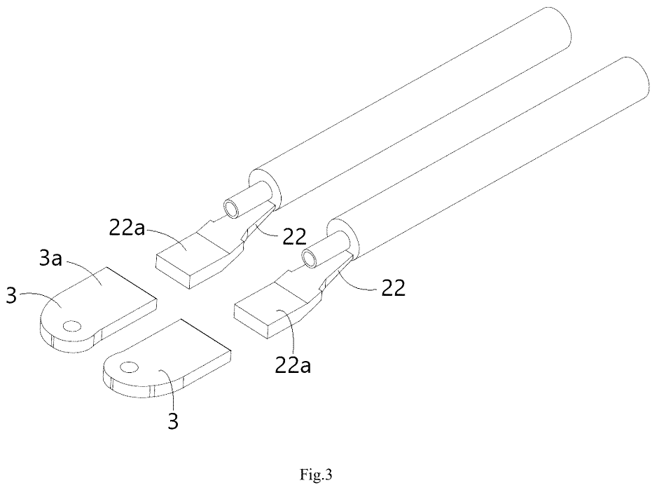

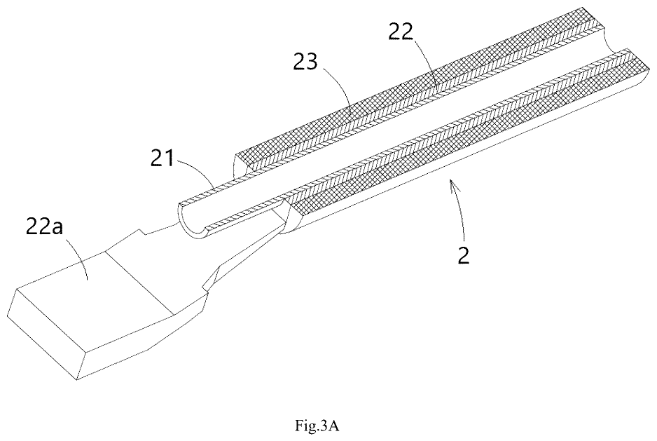

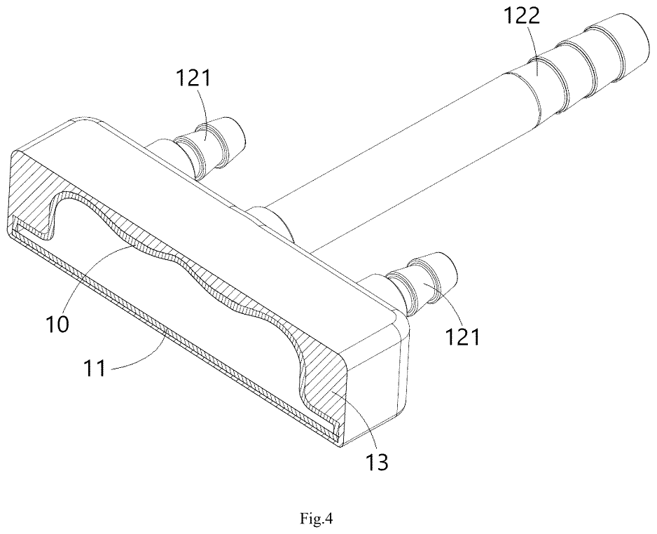

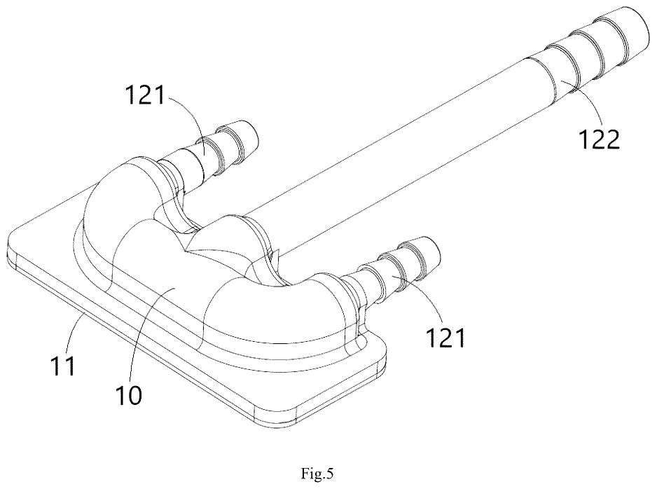

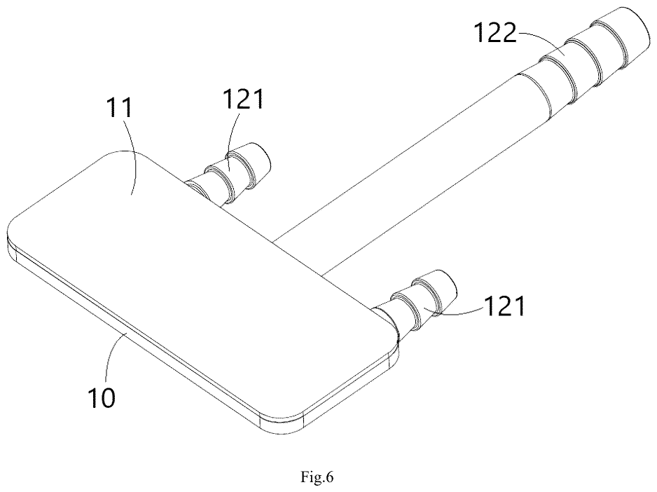

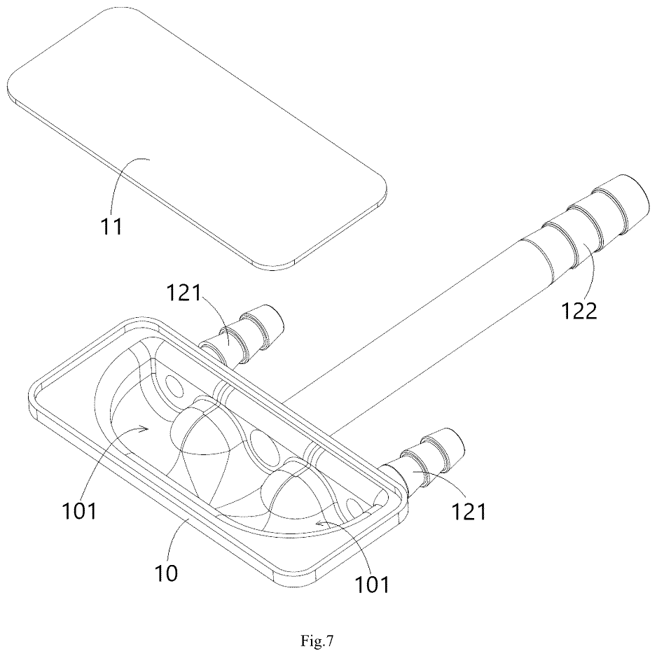

FIGS. 1 to 7 show a first embodiment according to the present invention. Among them, FIG. 1 shows an illustrative perspective view of an electrical connection module according to an exemplary first embodiment of the present invention; FIG. 2 shows an illustrative exploded view of an electrical connection module according to an exemplary first embodiment of the present invention; FIG. 3 shows an illustrative exploded view of the charging cable 2 and charging terminal 3 of the electrical connection module according to an exemplary first embodiment of the present invention; FIG. 3A shows a cross-sectional view of a charging cable 2 according to an exemplary first embodiment of the present invention; FIG. 4 shows a transverse sectional view of the cooling box 1 of the electrical connection module according to an exemplary first embodiment of the present invention; FIG. 5 shows an illustrative perspective view of the cooling box 1 according to an exemplary first embodiment of the present invention when viewed from the top, where the heat-conductive electric insulation layer 13 is not shown; FIG. 6 shows an illustrative perspective view of the cooling box 1 according to an exemplary first embodiment of the present invention when viewed from the bottom, where the heat-conductive electric insulation layer 13 is not shown; FIG. 7 shows an illustrative exploded view of the cooling box 1 according to an exemplary first embodiment of the present invention when viewed from the bottom, where the heat-conductive electric insulation layer 13 is not shown.

As shown in FIGS. 1 to 7, in an exemplary embodiment of the present invention, a cooling box 1 is disclosed. The cooling box 1 includes a box body 10, a bottom cover 11, multiple pipe joints 12, and a heat-conductive electric insulation layer 13, as shown in FIGS. 2 and 4. The box body 10 has a bottom opening. The bottom cover 11 is installed on the bottom opening of the box body 10. Multiple pipe joints 12 are integrally formed with the box body 10 and communicated with the interior of the box body 10, allowing cooling liquid to flow into or out of the box body 10 through the pipe joints 12. The heat-conductive electric insulation layer 13 is wrapped around the exterior of the box body 10 and the bottom cover 11. The bottom of cooling box 1 is suitable for thermal contact with charging terminal 3, so that the heat of charging terminal 3 can be transferred to the cooling liquid inside box body 10 through heat-conductive electric insulation layer and bottom cover 11 to cool charging terminal 3.

In an embodiment, the multiple pipe joints 12 and the box body 10 can be formed into an integral die-casted part or an integral machined part.

In an embodiment, the bottom cover 11 is welded to the box body 10, for example, it can be welded to the box body 10 through laser automatic welding technology, which can improve welding efficiency.

In an embodiment, the heat-conductive electric insulation layer 13 is an integral injection molded part directly injected onto the exterior of the box body 10 and the bottom cover 11. This can improve manufacturing efficiency. The function of the heat-conductive electric insulation layer 13 is to conduct heat and provide electrical insulation.

In an embodiment, the box body 10 and the bottom cover 11 are made of aluminum or aluminum alloy. However, the present invention is not limited to this, and the box body 10 and the bottom cover 11 may also be made of other suitable thermally conductive metals.

As shown in FIGS. 2 and 4 to 7, in the illustrated embodiment, the cooling box 1 includes a first pipe joint 121 and a second pipe joint 122. The first pipe joint 121 is used to connect with a cooling core pipe 21 of a charging cable 2, and the second pipe joint 122 is used to connect with an inlet pipe. The cooling liquid flows into cooling box 1 from the inlet pipe and flows out from cooling core pipe 21 of charging cable 2 to cool charging terminal 3 and charging cable 2.

However, the present invention is not limited to the illustrated embodiment. For example, in another exemplary embodiment of the present invention, the cooling box 1 includes a first pipe joint 121 and a second pipe joint 122. The first pipe joint 121 is used to connect with the cooling core pipe 21 of the charging cable 2, and the second pipe joint 122 is used to connect with an outlet pipe. The cooling liquid flows into the cooling box 1 from the cooling core pipe 21 of the charging cable 2 and flows out from the outlet pipe to cool the charging terminal 3 and the charging cable 2.

In the illustrated embodiment, the cooling box 1 includes two first pipe joints 121 and one second pipe joint 122, and one second pipe joint 122 is located between the two first pipe joints 121.

As shown in FIG. 7, in the illustrated embodiment, a flow channel 101 is formed in the housing 10 to connect multiple pipe joints 12, allowing the cooling liquid inside the housing 10 to flow smoothly between the multiple pipe joints 12 through the flow channel 101. The flow channel 101 is streamlined to ensure smooth flow of cooling liquid along flow channel 101.

In another exemplary embodiment of the present invention, an electrical connection module is also disclosed. The electrical connection module includes a cooling box 1 and a charging cable 2, as shown in FIG. 1. The charging cable 2 includes a cooling core pipe 21 and a conductor core 22 for electrical connection with a charging terminal 3, as shown in FIG. 2. The cooling core pipe 21 of charging cable 2 is connected to the pipe joint 12 of cooling box 1, allowing the cooling liquid to flow through the cooling box 1 and the charging cable 2.

As shown in FIG. 2, in the illustrated embodiment, the main body of the conductor core 22 of the charging cable 2 is tubular and wrapped around the outside of the cooling core pipe 21. The charging cable 2 also includes an outer insulation layer 23 wrapped around the main body of the conductor core 22.

As shown in FIG. 3, in the illustrated embodiment, the conductor core 22 has a connection end 22a exposed from the outer insulation layer 23, which is flat and suitable for being welded to the welding end 3a of the charging terminal 3. The cooling core pipe 21 of the charging cable 2 is exposed from the outer insulation layer 23 and is detachably connected to the first pipe joint 121.

In an embodiment, the cooling core pipe 21 of the charging cable 2 can serve as the outlet pipe. The electrical connection module also includes an inlet pipe, which is detachably connected to the second pipe joint 122 of the cooling box 1, for supplying cooling liquid to the cooling core pipe 21 of the cooling box 1 and the charging cable 2.

The present invention is not limited to the illustrated embodiment. For example, the cooling core pipe 21 of the charging cable 2 can also be used as an inlet pipe to supply cooling liquid to the cooling box 1. At this time, the electrical connection module also includes an outlet pipe, which is detachably connected to the second pipe joint 122 of the cooling box 1.

As shown in FIGS. 1 to 3, in the illustrated embodiment, the electrical connection module further comprises a charging terminal 3, which is electrically connected to the conductor core 22 of the charging cable 2. The bottom of cooling box 1 is in thermal contact with charging terminal 3 to cool it.

As shown in FIG. 3, in the illustrated embodiment, the charging terminal 3 has a flat welding end 3a, which has top and bottom surfaces opposite in its thickness direction. The cooling box 1 has a flat bottom surface, which is in thermal contact with the top surface of the welding end 3a of the charging terminal 3.

In the illustrated embodiment, the electrical connection module includes two charging cables 2 and two charging terminals 3. The cooling core pipes 21 of the two charging cables 2 are respectively connected to the two pipe joints 12 of the cooling box 1, and the conductor cores 22 of the two charging cables 2 are respectively electrically connected to the two charging terminals 3.

In an embodiment, the electrical connection module further includes a fixing device for fixing the cooling box 1 to the charging terminal 3, so that the bottom of the cooling box 1 is in reliable thermal contact with the charging terminal 3.

In another exemplary embodiment of the present invention, a charging device is also disclosed. The charging device comprises a housing and the aforementioned electrical connection module. The charging terminal 3 of the electrical connection module and the cooling box 1 are installed in the housing, and the charging cable 2 of the electrical connection module is led out from the rear end of the housing. In an embodiment, the charging device can be a charging dock or a charging gun.

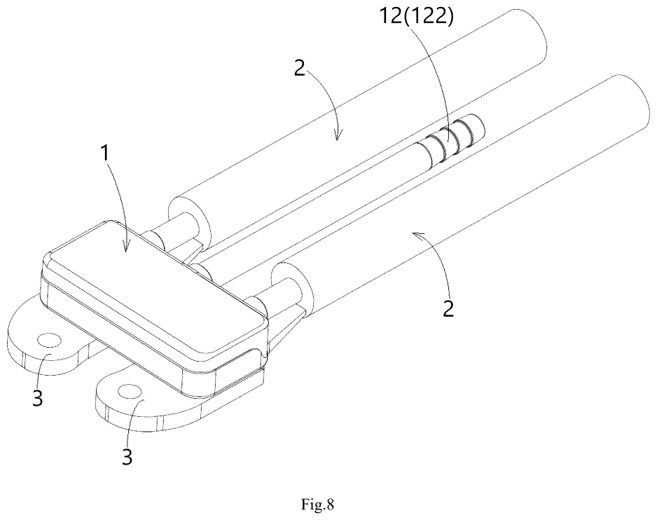

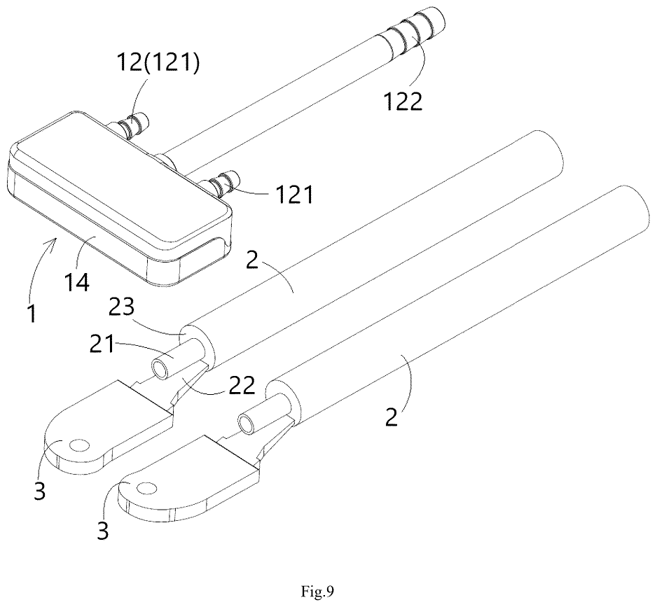

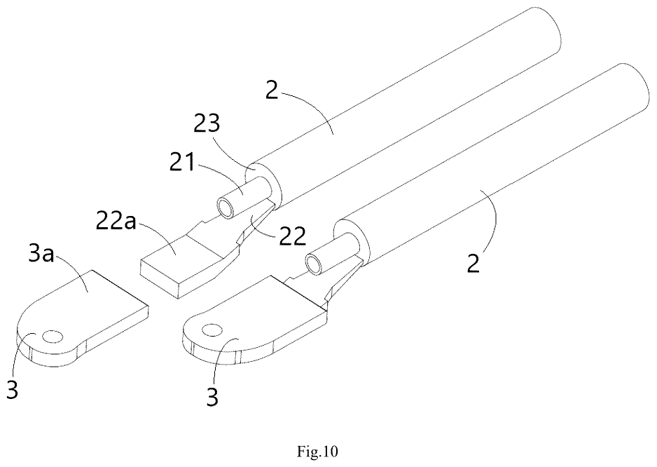

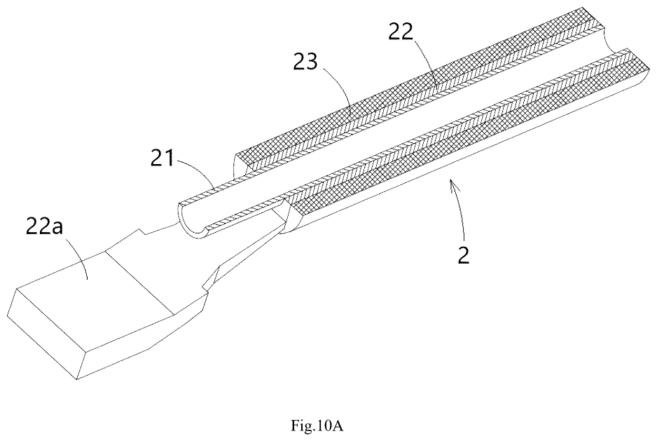

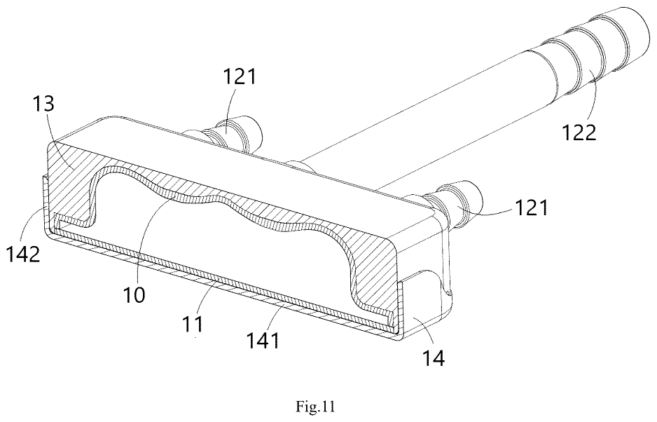

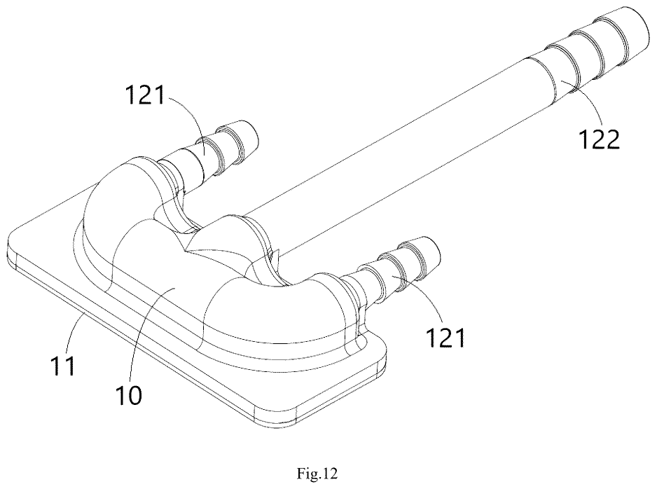

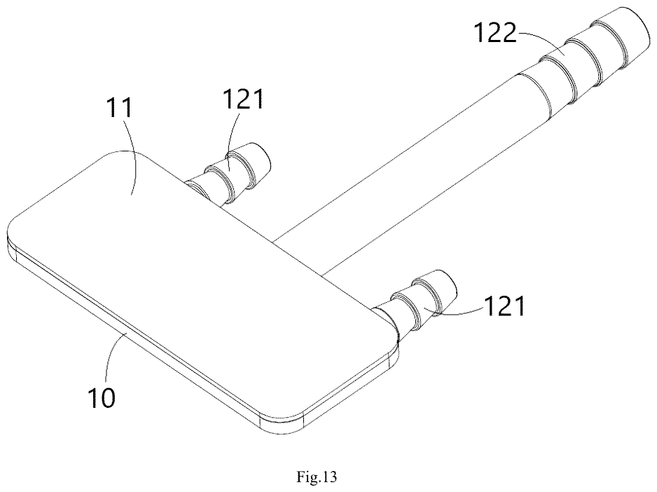

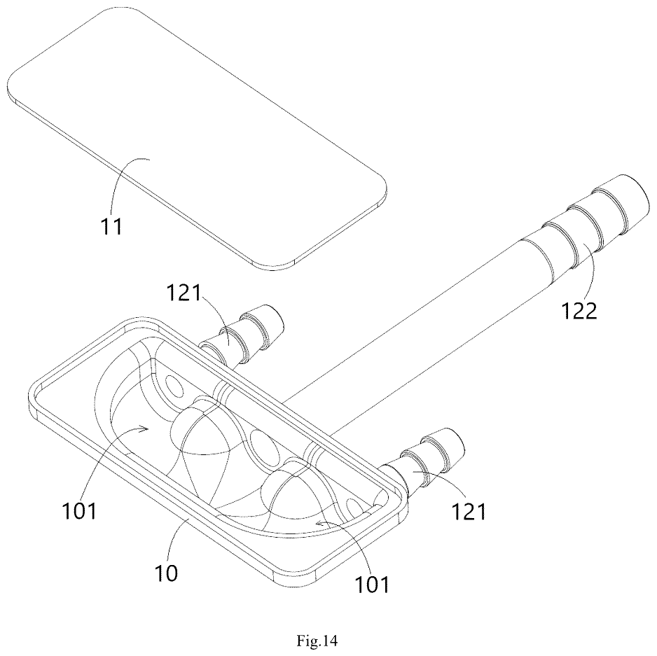

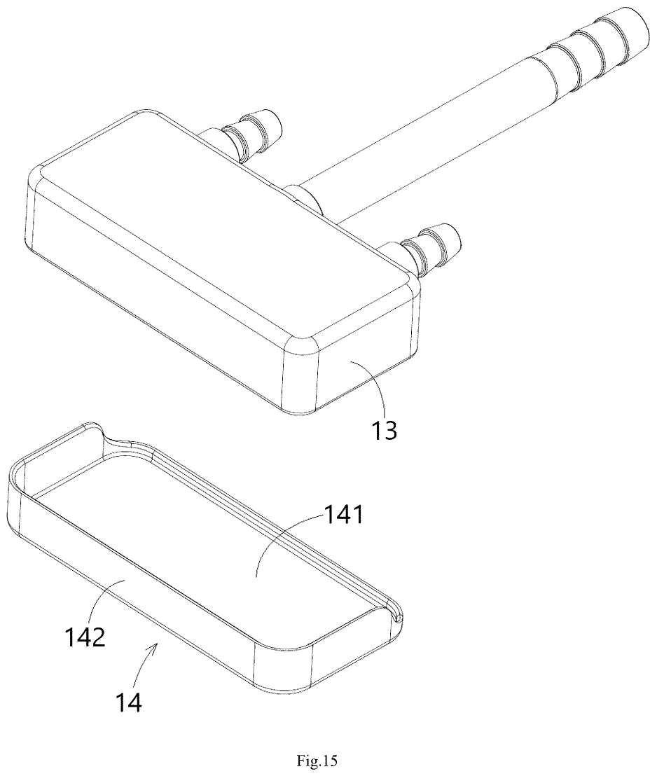

FIGS. 8 to 14 show a second embodiment according to the present invention. Among them, FIG. 8 shows an illustrative perspective view of an electrical connection module according to an exemplary second embodiment of the present invention; FIG. 9 shows an illustrative exploded view of an electrical connection module according to an exemplary second embodiment of the present invention; FIG. 10 shows an illustrative exploded view of the charging cable 2 and charging terminal 3 of the electrical connection module according to an exemplary second embodiment of the present invention; FIG. 10A shows a cross-sectional view of a charging cable 2 according to an exemplary second embodiment of the present invention; FIG. 11 shows a transverse sectional view of the cooling box 1 of the electrical connection module according to an exemplary second embodiment of the present invention; FIG. 12 shows an illustrative perspective view of a cooling box 1 according to an exemplary second embodiment of the present invention when viewed from the top, where the heat-conductive electric insulation layer 13 is not shown; FIG. 13 shows an illustrative perspective view of a cooling box 1 according to an exemplary second embodiment of the present invention when viewed from the bottom, where the heat-conductive electric insulation layer 13 is not shown; FIG. 14 shows an illustrative exploded view of a cooling box 1 according to an exemplary second embodiment of the present invention when viewed from the bottom, where the heat-conductive electric insulation layer 13 is not shown; FIG. 15 shows an illustrative exploded view of a cooling box 1 according to an exemplary second embodiment of the present invention, in which the heat-conductive electric insulation cap 14 has not yet been fitted onto the box body 10 of the cooling box 1.

As shown in FIGS. 8 to 14, in an exemplary embodiment of the present invention, a cooling box 1 is disclosed. The cooling box 1 includes: a box body 10, a bottom cover 11, multiple pipe joints 12, a heat-conductive electric insulation layer 13, and a heat-conductive electric insulation cap 14, as shown in FIGS. 9 and 11. Box body 10 has a bottom opening. The bottom cover 11 is installed on the bottom opening of the box body 10. Multiple pipe joints 12 are integrally formed with the box body 10 and communicated with the interior of the box body 10, allowing cooling liquid to flow into or out of the box body 10 through the pipe joints 12. The heat-conductive electric insulation layer 13 is wrapped around the outside of the box body 10. The peripheral wall 142 of the heat-conductive electric insulation cap 14 is fitted onto the heat-conductive electric insulation layer 13 at the lower part of the box body 10, and the bottom wall 141 of the heat-conductive electric insulation cap 14 is pressed against the bottom surface of the bottom cover 11. The bottom of cooling box 1 is suitable for thermal contact with charging terminal 3, so that the heat of charging terminal 3 can be transferred to the cooling liquid inside box body 10 through heat-conductive electric insulation layer 13 and bottom cover 11 to cool charging terminal 3.

In the illustrated embodiment, the peripheral wall 142 of the heat-conductive electric insulation cap 14 is interference fit with the heat-conductive electric insulation layer 13 at the lower part of the box body 10 to hold the heat-conductive electric insulation cap 14 onto the lower part of the box body 10.

In an embodiment, the heat-conductive electric insulation cap 14 can be an integral injection molded part with elasticity. This makes it easier to fit the heat-conductive electric insulation cap 14 onto the lower part of the box body 10.

In an embodiment, the multiple pipe joints 12 and the box body 10 can be formed into an integral die-casting part or an integral machined part.

In an embodiment, the bottom cover 11 is welded to the box body 10, for example, it can be welded to the box body 10 through laser automatic welding technology, which can improve welding efficiency.

In an embodiment, the heat-conductive electric insulation layer 13 is an integral injection molded part directly injected onto the outside of the box body 10. This can improve manufacturing efficiency. The function of the heat-conductive electric insulation layer 13 is to conduct heat and provide electrical insulation.

In an embodiment, the box body 10 and the bottom cover 11 are made of aluminum or aluminum alloy. However, the present invention is not limited to this, and the box body 10 and the bottom cover 11 may also be made of other suitable thermally conductive metals.

As shown in FIGS. 9 and 11 to 14, in the illustrated embodiment, the cooling box 1 includes a first pipe joint 121 and a second pipe joint 122. The first pipe joint 121 is used to connect with the cooling core pipe 21 of the charging cable 2, and the second pipe joint 122 is used to connect with an inlet pipe. The cooling liquid flows into cooling box 1 from the inlet pipe and flows out from cooling core pipe 21 of charging cable 2 to cool charging terminal 3 and charging cable 2.

However, the present invention is not limited to the illustrated embodiment. For example, in another exemplary embodiment of the present invention, the cooling box 1 includes a first pipe joint 121 and a second pipe joint 122. The first pipe joint 121 is used to connect with the cooling core pipe 21 of the charging cable 2, and the second pipe joint 122 is used to connect with an outlet pipe. The cooling liquid flows into the cooling box 1 from the cooling core pipe 21 of the charging cable 2 and flows out from the outlet pipe to cool the charging terminal 3 and the charging cable 2.

In the illustrated embodiment, the cooling box 1 includes two first pipe joints 121 and one second pipe joint 122, and one second pipe joint 122 is located between the two first pipe joints 121.

As shown in FIG. 14, in the illustrated embodiment, a flow channel 101 is formed in the housing 10 to connect multiple pipe joints 12, allowing the cooling liquid inside the housing 10 to flow smoothly between the multiple pipe joints 12 through the flow channel 101. The flow channel 101 is streamlined to ensure smooth flow of cooling liquid along the flow channel 101.

In another exemplary embodiment of the present invention, an electrical connection module is also disclosed. The electrical connection module includes a cooling box 1 and a charging cable 2, as shown in FIG. 8. The charging cable 2 includes a cooling core pipe 21 and a conductor core 22 for electrical connection with a charging terminal 3. The cooling core pipe 21 of charging cable 2 is connected to the pipe joint 12 of cooling box 1, allowing the cooling liquid to flow through the cooling box 1 and the charging cable 2.

As shown in FIG. 9, in the illustrated embodiment, the main body of the conductor core 22 of the charging cable 2 is tubular and wrapped around the outside of the cooling core pipe 21. The charging cable 2 also includes an outer insulation layer 23 wrapped around the main body of the conductor core 22.

As shown in FIG. 10, in the illustrated embodiment, the conductor core 22 has a connection end 22a exposed from the outer insulation layer 23, which is flat and suitable for being welded to the welding end 3a of the charging terminal 3. The cooling core pipe 21 of the charging cable 2 is exposed from the outer insulation layer 23 and is detachably connected to the first pipe joint 121.

In the illustrated embodiment, the cooling core pipe 21 of the charging cable 2 can serve as the outlet pipe. The electrical connection module also includes an inlet pipe, which is detachably connected to the second pipe joint 122 of the cooling box 1, for supplying cooling liquid to the cooling core pipe 21 of the cooling box 1 and the charging cable 2.

However, the present invention is not limited to the illustrated embodiment. For example, the cooling core pipe 21 of the charging cable 2 can also be used as an inlet pipe to supply cooling liquid to the cooling box 1. At this time, the electrical connection module also includes an outlet pipe, which is detachably connected to the second pipe joint 122 of the cooling box 1.

As shown in FIGS. 8 to 10, in the illustrated embodiment, the electrical connection module further includes a charging terminal 3, which is electrically connected to the conductor core 22 of the charging cable 2. The bottom of cooling box 1 is in thermal contact with the charging terminal 3 to cool it.

As shown in FIG. 10, in the illustrated embodiment, the charging terminal 3 has a flat welding end 3a, which has top and bottom surfaces opposite in its thickness direction. The cooling box 1 has a flat bottom surface, which is in thermal contact with the top surface of the welding end 3a of the charging terminal 3.

In the illustrated embodiment, the electrical connection module includes two charging cables 2 and two charging terminals 3. The cooling core pipes 21 of the two charging cables 2 are respectively connected to the two pipe joints 12 of the cooling box 1, and the conductor cores 22 of the two charging cables 2 are respectively electrically connected to the two charging terminals 3.

In an embodiment, the electrical connection module further includes a fixing device for fixing the cooling box 1 to the charging terminal 3, so that the bottom of the cooling box 1 is in reliable thermal contact with the charging terminal 3.

In another exemplary embodiment of the present invention, a charging device is also disclosed. The charging device comprises a housing and the aforementioned electrical connection module. The charging terminal 3 and the cooling box 1 of the electrical connection module are installed in the housing, and the charging cable 2 of the electrical connection module is led out from the rear end of the housing.

In various embodiments, the charging device can be a charging dock or a charging gun.

In the aforementioned exemplary embodiments according to the present invention, the pipe joint and the box body are integrally formed, and the box body and the bottom cover are directly wrapped in the heat-conductive electric insulation layer. Therefore, the present invention does not require welding the pipe joint and pasting the heat-conductive electric insulation film, simplifying the manufacturing process of the cooling box and reducing manufacturing costs.

In the aforementioned exemplary embodiments according to the present invention, the pipe joint and the box body are integrally formed, and the lower part and bottom cover of the box body are fitted in the heat-conductive electric insulation cap. Therefore, the present invention does not require welding the pipe joint and pasting the heat-conductive electric insulation film, simplifying the manufacturing process of the cooling box and reducing manufacturing costs.

In addition, in the aforementioned exemplary embodiments according to the present invention, a flow channel connecting multiple pipe joints is formed in the housing, allowing the cooling liquid to flow smoothly between the multiple pipe joints through the flow channel, thereby improving the cooling effect.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A cooling box, comprising:
a box body with a bottom opening;
a bottom cover installed on the bottom opening of the box body;
a plurality of pipe joints integrally formed with the box body and communicated with an interior of the box body to allow a cooling liquid to flow into or out of the box body through the pipe joints; and
a heat-conductive electric insulation layer wrapped around an outside of the box body, an exterior of the bottom cover is wrapped by the heat-conductive electric insulation layer or by a heat-conductive electric insulation cap that is fitted onto a lower part of the box body, the cooling box thermally contacts a charging terminal to transfer heat of the charging terminal to the cooling liquid inside the box body through the heat-conductive electric insulation layer and the bottom cover to cool the charging terminal.

2. The cooling box according to claim 1, wherein the pipe joints and the box body are formed into an integral die-casted part or an integral machined part.

3. The cooling box according to claim 1, wherein the bottom cover is welded to the box body.

4. The cooling box according to claim 1, wherein the exterior of the bottom cover is wrapped by the heat-conductive electric insulation layer, which is an integral injection molded part that is injected onto an exterior of the box body and the bottom cover.

5. The cooling box according to claim 1, wherein the exterior of the bottom cover is wrapped by the heat-conductive electric insulation cap that is fitted onto the lower part of the box body, a peripheral wall of the heat-conductive electric insulation cap is fitted onto the heat-conductive electric insulation layer at a lower part of the box body, and a bottom wall of the heat-conductive electric insulation cap is attached to a bottom surface of the bottom cover.

6. The cooling box according to claim 5, wherein the peripheral wall of the heat-conductive electric insulation cap is interference fit with the heat-conductive electric insulation layer at the lower part of the box body to hold the heat-conductive electric insulation cap onto the lower part of the box body.

7. The cooling box according to claim 5, wherein the heat-conductive electric insulation cap is an integral injection molded part with elasticity.

8. The cooling box according to claim 1, wherein the box body and the bottom cover are aluminum parts or aluminum alloy parts.

9. The cooling box according to claim 1, wherein the pipe joints include a first pipe joint and a second pipe joint, the first pipe joint connects with a cooling core pipe of a charging cable and the second pipe joint connects with an inlet pipe, the cooling liquid flows into the cooling box through the inlet pipe and flows out from the cooling core pipe of the charging cable to cool the charging terminal and the charging cable.

10. The cooling box according to claim 1, wherein the pipe joints include a first pipe joint and a second pipe joint, the first pipe joint connects with a cooling core pipe of a charging cable and the second pipe joint connects with an outlet pipe, the cooling liquid flows into the cooling box from the cooling core pipe of the charging cable and flows out from the outlet pipe to cool the charging terminal and the charging cable.

11. The cooling box according to claim 9, wherein the first pipe joint is one of a pair of first pipe joints, the second pipe joint is between the pair of first pipe joints.

12. The cooling box according to claim 1, wherein a flow channel connecting the pipe joints is formed in the box body, the flow channel is streamlined, allowing the cooling liquid inside the box body to flow smoothly between the pipe joints through the flow channel.

13. An electrical connection module, comprising:
a cooling box including:
a box body with a bottom opening;
a bottom cover installed on the bottom opening of the box body;
a plurality of pipe joints integrally formed with the box body and communicated with an interior of the box body to allow a cooling liquid to flow into or out of the box body through the pipe joints; and
a heat-conductive electric insulation layer wrapped around an outside of the box body, an exterior of the bottom cover is wrapped by the heat-conductive electric insulation layer or by a heat-conductive electric insulation cap that is fitted onto a lower part of the box body, the cooling box thermally contacts a charging terminal to transfer heat of the charging terminal to the cooling liquid inside the box body through the heat-conductive electric insulation layer and the bottom cover to cool the charging terminal; and
a charging cable including a cooling core pipe and a conductor core for electrical connection with the charging terminal, the cooling core pipe of the charging cable is connected to one of the pipe joints of the cooling box, allowing the cooling liquid to flow through the cooling box and the charging cable.

14. The electrical connection module according to claim 13, wherein a main body of the conductor core of the charging cable is tubular and wrapped around an outside of the cooling core pipe, the charging cable includes an outer insulation layer wrapped around the main body of the conductor core.

15. The electrical connection module according to claim 14, wherein the conductor core has a connection end exposed from the outer insulation layer, the connection is flat and suitable for being welded to a welding end of the charging terminal, the cooling core pipe of the charging cable is exposed from the outer insulation layer and is detachably connected to one of the pipe joints.

16. The electrical connection module according to claim 13, further comprising the charging terminal electrically connected to the conductor core of the charging cable, a bottom of the cooling box is in thermal contact with the charging terminal to cool the charging terminal.

17. The electrical connection module according to claim 16, wherein the charging terminal has a flat welding end, which has a top surface and a bottom surface opposite in a thickness direction, the cooling box has a flat bottom surface, and the flat bottom surface of the cooling box is in thermal contact with the top surface of the flat welding end of the charging terminal.

18. The electrical connection module according to claim 16, wherein the charging cable is one of a pair of charging cables and the charging terminal is one of a pair of charging terminals, the cooling core pipes of the charging cables are respectively connected to the pipe joints of the cooling box, and the conductor cores of the charging cables are respectively electrically connected to the pair of charging terminals.

19. The electrical connection module according to claim 16, further comprising a fixing device fixing the cooling box to the charging terminal, so that the bottom of the cooling box is in thermal contact with the charging terminal.

20. A charging device, comprising:
a housing; and
an electrical connection module, including:
a cooling box including:
a box body with a bottom opening;
a bottom cover installed on the bottom opening of the box body;
a plurality of pipe joints integrally formed with the box body and communicated with an interior of the box body to allow a cooling liquid to flow into or out of the box body through the pipe joints; and
a heat-conductive electric insulation layer wrapped around an outside of the box body, an exterior of the bottom cover is wrapped by the heat-conductive electric insulation layer or by a heat-conductive electric insulation cap that is fitted onto a lower part of the box body, the cooling box thermally contacts a charging terminal to transfer heat of the charging terminal to the cooling liquid inside the box body through the heat-conductive electric insulation layer and the bottom cover to cool the charging terminal; and
a charging cable including a cooling core pipe and a conductor core for electrical connection with the charging terminal, the cooling core pipe of the charging cable is connected to one of the pipe joints of the cooling box, allowing the cooling liquid to flow through the cooling box and the charging cable, the charging terminal and the cooling box of the electrical connection module are installed in the housing, and the charging cable of the electrical connection module is led out from a rear end of the housing.

21. The charging device according to claim 20, wherein the charging device is a charging dock or a charging gun.
